(19) United States
(12) Patent Application Publication
(10) Pub. No.: US 2010/0081286 A1
(43) Pub. Date: Apr. 1, 2010

(54) Method of etching carbon-containing layer, method of forming contact hole using the same, and method of manufacturing semiconductor device using the same

(76) Inventors: Nam-Gun Kim, Hwasung-City (KR); Sung-Il Cho, Hwasung-City (KR); Yeong-Hun Han, Hwasung-City (KR)

Correspondence Address: LEE & MORSE, P.C., 3141 FAIRVIEW PARK DRIVE, SUITE 500, FALLS CHURCH, VA, 22042, US

(21) Appl. No.: 12/585,485

(22) Filed: Sep. 16, 2009

(30) Foreign Application Priority Data
Sep. 17, 2008 (KR) 10-2008-0090874

(51) Int. Cl. H01L 21/3065

(52) U.S. Cl. 438/710; 257/E21.218

(57) ABSTRACT

A method of etching a carbon-containing layer, a method of forming a contact hole using the same, and a method of manufacturing a semiconductor device using the same, the method of etching a carbon-containing layer including forming a capping layer pattern on a carbon-containing layer to expose a portion of the carbon-containing layer, and plasma etching the exposed portion of the carbon-containing layer using an etching gas, wherein the etching gas includes oxygen gas and an inert gas, the inert gas being xenon gas or a gas mixture of xenon gas and argon gas.

### BACKGROUND

1. Field

Embodiments relate to a method of etching a carbon-containing layer, a method of forming a contact hole using the same, and a method of manufacturing a semiconductor device using the same.

2. Description of the Related Art

As semiconductor devices have become more highly integrated and a feature size thereof has correspondingly decreased, horizontal areas of the semiconductor devices have also decreased, while vertical dimensions of such semiconductor devices have increased. As a result, heights of unit elements and contacts for electrically connecting the unit elements have increased. Thus, aspect ratios of corresponding contact holes have also increased. In an etching process for forming a pattern having contact holes with such an increased aspect ratio, a thickness of a layer to be etched has become larger. Thus, there may be essentially no etching process margin due to the height of the photoresist pattern that should be used. Therefore, it is desirable that the thickness of the photoresist layer is decreased. However, a relatively thin photoresist layer produces new problems. To solve the problems associated with the photoresist pattern being thin, a technique of using a carbon-containing layer, e.g., an amorphous carbon layer (ACL), as an etch mask has been developed.

An etch mask including an ACL may be employed in forming a fine pattern of a highly-integrated semiconductor device (on the scale of microns or smaller). The etching mask including an ACL may have a multilayer structure in which an ACL, a capping layer, and a photoresist layer are sequentially stacked on a layer to be etched. A photoresist pattern may then be formed through exposure and development processes. That pattern may then be transferred to an optional anti-reflection layer and the capping layer, thus producing a capping layer pattern. The ACL may then be etched using the capping layer pattern as a first etch mask. An image of the capping layer pattern may be transferred to the ACL, thus producing an ACL pattern. Such an ACL pattern may then be used as a second etch mask for etching the film to be etched on the substrate.

### SUMMARY

Embodiments are directed to a method of etching a carbon-containing layer, a method of forming a contact hole using the same, and a method of manufacturing a semiconductor device using the same, which substantially overcome one or more of the drawbacks, limitations, and/or disadvantages of the related art.

It is a feature of an embodiment to provide a method of etching a carbon-containing layer that reduces a skew in a critical dimension of a pattern.

It is another feature of an embodiment to provide a method of forming a contact hole in an insulation layer that reduces a size of the contact hole while suppressing skew variations of contact holes regardless of a difference in a shape or a size of the contact holes.

At least one of the above and other features and advantages may be realized by providing a method of etching a carbon-containing layer including forming a capping layer pattern on a carbon-containing layer to expose a portion of the carbon-containing layer, and plasma etching the exposed portion of the carbon-containing layer using an etching gas, wherein the etching gas includes oxygen gas and an inert gas, the inert gas being xenon gas or a gas mixture of xenon gas and argon gas.

An amount of the inert gas included in the etching gas may be about 25% to about 50% by volume, based on the total volume of the etching gas.

The inert gas may be the gas mixture of xenon gas and argon gas, and a ratio {Xe/(Ar+Xe)} of an amount of xenon gas to a total amount of xenon gas and argon gas in the gas mixture may be about 0.2 to about 1.0.

The ratio {Xe/(Ar+Xe)} of the amount of gas to the total amount of xenon gas and argon gas may be about 0.5 to about 1.0.

An amount of xenon gas in the etching gas may be about 5% to about 50% by volume, based on the total volume of the etching gas.

Plasma etching the carbon-containing layer may further include providing a passivation gas including at least one of CO, HBr, Cl₂, COS, N₂, SO₂, NO, and NO₂.

The carbon-containing layer may include at least one of an amorphous carbon layer (ACL), a carbon based spin-on hardmask (C—SOH), and a nanocarbon polymer.

The method may include forming a capping layer on the carbon-containing layer such that the capping layer includes at least one of a silicon oxide layer, a silicon oxynitride layer, a silicon layer, a silicon germanium layer, and a polysilicon layer, wherein the forming the capping layer pattern includes forming a photoresist pattern on the capping layer, and patterning the capping layer by performing an etching process using the photoresist pattern as an etching mask.

The method may further include forming an organic anti-reflective coating layer on the capping layer.

At least one of the above and other features and advantages may also be realized by providing a method of forming an insulation layer having a contact hole including forming an insulation layer on a substrate, sequentially forming a carbon-containing layer and a capping layer on the insulation layer, forming a photoresist pattern on the capping layer, the photoresist pattern including a first hole and a second hole having a size or a shape different from a size or a shape of the first hole, partially etching the capping layer using the photoresist pattern on the capping layer as a mask to form a capping layer pattern which partially exposes the carbon-containing layer, etching a portion of the carbon-containing layer exposed by the capping layer pattern using an etching gas that includes oxygen gas and an inert gas including xenon gas to form a carbon-containing layer pattern on the layer, and etching a portion of the insulation layer exposed by the carbon-containing layer pattern to form a first contact hole and a second contact hole in the insulation layer.

At least one of the first contact hole and the second contact hole may have a width of about 50 nm or less.

The first contact hole may have a round shape, and the second contact hole may have a bar shape having an aspect ratio of at least about 2.

The carbon-containing layer may include at least one of an amorphous carbon layer (ACL), a carbon based spin-on hardmask (C—SOH), and a nanocarbon polymer, and the capping layer may include at least one of a silicon oxide layer, a silicon oxynitride layer, a silicon layer, a silicon germanium layer, and a polysilicon layer.

The method may further include forming an organic anti-reflective coating layer on the capping layer.

The inert gas may include argon gas.

A ratio {Xe/(Ar+Xe)} of an amount of xenon gas to a total amount of xenon gas and argon gas may be about 0.2 to about 1.0.

The etching a portion of the carbon-containing layer may further include providing a passivation gas including at least of CO, HBr, Cl₂, COS, N₂, SO₂, NO, and NO₂.

A first skew may exist between the first hole in the photoresist pattern and the first contact hole of the insulation layer, a second skew may exist between the second hole in the photoresist pattern and the second contact hole of the insulation layer, and a dimensional difference between the first skew and the second skew is about 15 nm or less.

At least one of the above and other features and advantages may also be realized by providing a method of manufacturing a semiconductor device including forming an insulating interlayer on a substrate, sequentially forming a carbon-containing layer and a capping layer on the insulating interlayer, forming a photoresist pattern on the capping layer, the photoresist pattern including a plurality of first holes having a round shape and a plurality of second holes having one of a bar shape or a line shape, partially etching the capping layer using the photoresist pattern on the capping layer as a mask to form a capping layer pattern, etching a portion of the carbon-containing layer exposed by the capping layer pattern using an etching gas that includes oxygen gas and an inert gas including xenon gas to form a carbon-containing layer pattern on the layer, etching a portion of the insulation layer exposed by the carbon-containing layer pattern to form a plurality of first contact holes in the insulation layer corresponding to the first holes and a plurality of second contact holes in the insulation layer corresponding to the second holes, and filling the plurality of first contact holes and the plurality of second contact holes with a conductive material to form a plurality of first contacts and a plurality of second contacts on the substrate, wherein at least one of the first contacts and the second contacts has a width of about 50 nm or less.

### BRIEF DESCRIPTION OF THE DRAWINGS

The above and other features and advantages will become more apparent to those of ordinary skill in the art by describing in detail exemplary embodiments with reference to the attached drawings, in which:

FIG. 1 illustrates a flow chart of a method of etching a carbon-containing layer according to an embodiment;

FIGS. 2 through 5 illustrate cross-sectional views of stages in a method of forming a contact hole according to an embodiment;

FIG. 6 illustrates a layout view of an NAND-type flash memory device manufactured by the method of forming a contact hole according to an embodiment;

FIGS. 7 through 10 illustrate cross-sectional views of stages in a method of manufacturing an NAND-type flash memory device according to an embodiment;

FIG. 11 illustrates SEM images of contact holes obtained by varying a ratio of xenon gas and argon gas in an etching gas;

FIG. 12 illustrates a graph showing skew variations of contact holes obtained by varying the ratio of xenon gas and argon gas in an etching gas;

FIG. 13 illustrates a graph showing variation of an etching rate of amorphous carbon layer according to the ratio of xenon gas and argon gas in an etching gas;

FIG. 14 illustrates a block diagram of a memory device according to an embodiment.

FIG. 15 illustrates a block diagram of a portable device according to an embodiment; and

FIG. 16 illustrates a block diagram of a computer system according to an embodiment.

### DETAILED DESCRIPTION

Korean Patent Application No. 10-2008-0090874, filed on Sep. 17, 2008, in the Korean Intellectual Property Office, and entitled: “Methods of Etching a Carbon-Containing Layer and Methods of Forming a Contact Hole,” is incorporated by reference herein in its entirety.

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the drawing figures, the dimensions of layers and regions may be exaggerated for clarity of illustration. It will also be understood that when a layer or element is referred to as being “on” another layer or substrate, it can be directly on the other layer or substrate, or intervening layers may also be present. Further, it will be understood that when a layer is referred to as being “under” another layer, it can be directly under, and one or more intervening layers may also be present. In addition, it will also be understood that when a layer is referred to as being “between” two layers, it can be the only layer between the two layers, or one or more intervening layers may also be present. Like reference numerals refer to like elements throughout.

It will be understood that when an element or layer is referred to as being “connected to” or “coupled to” another element or layer, it may be directly connected or coupled to the other element or layer or intervening elements or layers may be present. In contrast, when an element is referred to as being “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of example embodiments.

Spatially relative terms, e.g., “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of example embodiments. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of idealized example embodiments (and intermediate structures). As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle may, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms including technical and scientific terms used herein have the same meaning as commonly understood by one of ordinary skill in the art to which example embodiments belongs. It will be further understood that terms, e.g., those defined in commonly used dictionaries, should be interpreted as having a meaning that is consistent with their meaning in the context of the relevant art and will not be interpreted in an idealized or overly formal sense unless expressly so defined herein.

Method of Etching a Carbon-Containing Layer

FIG. 1 illustrates a flowchart of a method of etching a carbon-containing layer according to an embodiment. Referring to FIG. 1, a carbon-containing layer may be formed on a substrate (S110). The substrate may include, e.g., a silicon wafer. In an implementation, the carbon-containing layer may be formed using a material including carbon and hydrogen. In another implementation, the carbon-containing layer may be formed using a material including carbon, hydrogen, and oxygen. For example, the carbon-containing layer may be formed using an amorphous carbon layer (ACL), APF (manufactured by AMAT Corp.), SiLK (manufactured by Dow Chemical Co.), a nanocarbon polymer NCP (manufactured by ASM), AHM (manufactured by Novellous), a carbon based spin-on hardmask (C—SOH) layer, etc. A thickness of the carbon-containing layer may be appropriately selected by considering the thickness of a layer to be etched. The carbon-containing layer may be formed to a thickness of, e.g., about 1,000 to about 2,000 Å.

Prior to forming the carbon-containing layer on the substrate, a conductive structure and/or an insulation layer covering a conductive structure may be formed on the substrate. In an implementation, the layer to be etched may be formed on the substrate before forming the carbon-containing layer. The carbon containing layer may then be formed on the layer to be etched. The layer to be etched may include an insulation layer (e.g., a silicon oxide layer, a silicon nitride layer, a silicon oxynitride layer, etc.), a conductive layer (e.g., a metal layer, a metal alloy layer, a metal layer doped with impurities, a polysilicon layer, a doped polysilicon layer, a metal silicide layer, a metal nitride layer, etc.), and/or a semiconductor layer (a silicon layer, a silicon germanium layer, a carbon doped semiconductor layer, etc.).

A capping layer pattern may then be formed on the carbon-containing layer (S120). The capping layer pattern may be, e.g., an etching mask for patterning the carbon-containing layer. First, a capping layer may be formed on the carbon-containing layer. The capping layer may include a layer that facilitates low-temperature deposition, e.g., deposition at a temperature of about 400° C. or less. The capping layer may include, e.g., silicon oxynitride, plasma-enhanced (PE) oxide, tetraethyl orthosilicate (TEOS), atomic layer deposition (ALD) oxide, Si, and/or SiGe. Then, a photoresist pattern may be formed on the capping layer. The photoresist pattern may include, e.g., ArF photoresist. The photoresist pattern may include a first hole having a first width and a second hole having a second width. In an implementation, the second width of the second hole may be at least about two times larger than the first width of the first hole. The capping layer may be patterned using the photoresist pattern as a mask to form a capping layer pattern.

In an implementation, an anti-reflective film may be formed on the capping layer prior to forming the photoresist pattern on the capping layer. For example, an organic anti-reflective film may be formed to a thickness of about 300 to about 500 Å. After forming the photoresist pattern on the anti-reflective film, the capping layer may be patterned using the photoresist pattern as a mask. As a result, the capping layer pattern may be formed on the carbon-containing layer. The photoresist pattern may then be partially or totally removed from the substrate during an etching process for patterning the capping layer. In an implementation, the photoresist pattern may be removed by, e.g., an ashing process or a stripping process.

The carbon-containing layer may be etched using an etching gas including, e.g., oxygen gas and xenon gas (S130). The etching process may include, e.g., a dry etching process or a plasma etching process. In the etching process, the capping layer pattern may be employed as an etching mask. By performing the etching process, a carbon-containing layer pattern may be formed on the substrate. The carbon-containing layer pattern may include at least one hole. In an implementation, the carbon-containing layer pattern may include a third hole corresponding to the first hole of the photoresist pattern and a fourth hole corresponding to the second hole of the photoresist pattern. When a layer to be etched is formed on the substrate, the carbon-containing layer pattern formed on the layer may be used as an etching mask for etching the layer.

In an implementation, the etching process may include, e.g., a dry etching process using plasma. The etching process may be carried out using a plasma etching apparatus employing, e.g., inductively coupled plasma (ICP) or dual frequency capacitively coupled plasma (CCP).

In an implementation, the etching gas used in the etching process may include, e.g., oxygen gas as a base gas and xenon gas. In another implementation, the etching gas used in the etching process may include, e.g., oxygen gas as a base gas and a gas mixture of xenon gas and argon gas. In still another implementation, the etching gas may include, e.g., oxygen and an inert gas. For example, the inert gas may be xenon gas (Xe) or a gas mixture of xenon gas and at least one other inert gas (e.g., Ar, Ne, Kr, etc.).

In an implementation, a ratio {Xe/(Ar+Xe)} of an amount of xenon gas to the total amount of the mixture of xenon gas and argon gas may be about 0.2 to about 1.0. In addition, the amount of oxygen gas in the etching gas is about 50 to about 75% by volume, the amount of xenon gas or the gas mixture of xenon gas and argon gas may be about 25 to about 50% by volume. An amount of xenon gas in the etching gas may be about 5 to about 50% by volume. Maintaining the amount of the xenon gas from about 5 to about 50% by volume may help ensure that an etching rate and/or an etching ability of the carbon-containing layer is improved and the anisotropic etching ability of the plasma etching process is enhanced, due to an increase in an ion flux amount of the etching gas. When the ratio of the amount of xenon gas to the total amount of the gas mixture of xenon gas and argon gas is about 0.5 to about 1.0, an etching rate of the carbon-containing layer may be about 5,450 to about 5,600 Å/min.

Xenon gas included in the etching gas may have an ionization energy lower than that of argon gas and, therefore, xenon gas may be readily ionized to raise the ion flux of plasma in the etching gas, thereby improving anisotropic etching ability. In the etching process for forming holes in an insulation layer using a carbon-containing mask layer, the size of the holes formed in the insulation layer may decrease as the relative amount of xenon gas increases in the etching gas used to etch the carbon-containing layer. Further, when contact holes having at least two different sizes and/or shapes are formed in the insulation layer using the carbon-containing mask layer, the size of the contact holes may vary proportionally to each other regardless of the sizes and/or shapes of the contact holes as the amount of xenon gas in the inert gas portion of the gas for etching the carbon-containing layer varies. Therefore, the size of the holes may be readily adjusted by varying the amount of xenon gas in the etching gas for etching the carbon-containing layer.

In an implementation, a passivation gas may be used in the plasma etching process for etching the carbon-containing layer. The passivation gas may be provided together with the etching gas to improve anisotropic etching of the carbon-containing layer. For example, CO, HBr, Cl₂, COS, N₂, SO₂, NO, and/or NO₂ may be used as the passivation gas.

The carbon-containing layer may be plasma-etched using an etching gas including xenon gas so that an etching rate or an etching ability of the carbon-containing layer may be improved. In addition, the anisotropic etching ability of the plasma etching process may be enhanced due to an increase in an ion flux amount of the etching gas. Therefore, the carbon-containing layer may have a relatively uniform profile and/or dimension. Undesirable bottom widening of a hole and/or formation of a hole larger than a predetermined dimension may also be reduced or suppressed.

Method of Forming an Insulation Layer Having a Contact Hole

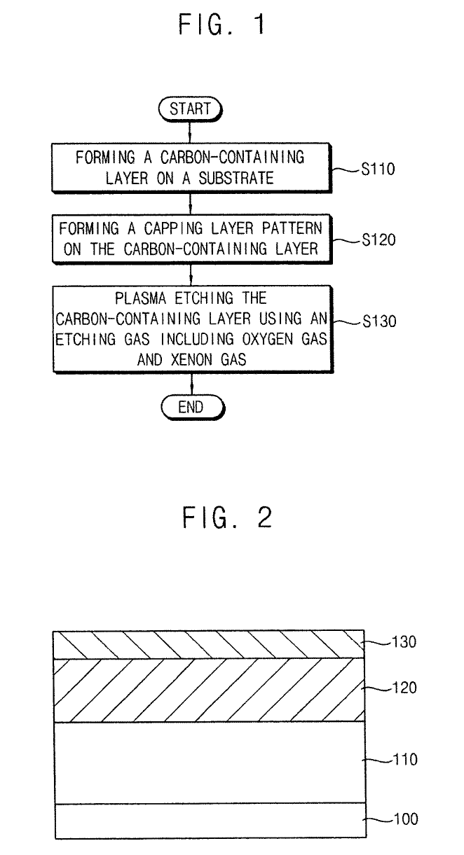

FIGS. 2 through 5 illustrate cross-sectional views of stages in a method of forming an insulation layer having a contact hole according to an embodiment. Referring to FIG. 2, a substrate 100 may include an insulating interlayer 110 thereon covering a memory cell or a gate structure on the substrate 100. The insulating interlayer 110 may be partially etched to include contact holes having different dimensions and shapes. The insulating interlayer 110 may include an insulating material, e.g., an oxide material. For example, the insulating interlayer 110 may be formed using silicon oxide. The silicon oxide may include, e.g., BPSG (boro-phosphor silicate glass), PSG (phosphor silicate glass), USG (undoped silicate glass), SOG (spin on glass), PE-TEOS (plasma enhanced-tetraethyl orthosilicate), O₃-TEOS (ozone TEOS), etc.

A carbon-containing layer 120 and a capping layer 130 may be sequentially formed on the insulating interlayer 110. The carbon-containing layer 120 may be formed of, e.g., a carbon-containing material including carbon and hydrogen. In an implementation, the carbon-containing layer 120 may be formed using, e.g., a carbon-containing material including carbon, hydrogen, and oxygen. The carbon-containing layer may be formed using, e.g., amorphous carbon layer (ACL), APF (manufactured by AMAT Corp.), SiLK (manufactured by Dow Chemical Co.), NCP (manufactured by ASM), AHM (manufactured by Novellous), a carbon based spin-on hardmask (C—SOH) layer, etc. The carbon-containing layer 120 may be formed by, e.g., a chemical vapor deposition process or a spin-coating process.

The capping layer 130 may serve as a mask for etching the carbon-containing layer 120 and/or the insulating interlayer 110. Thus, the capping layer 130 may be formed from a material having an etching selectivity relative to the carbon-containing layer 120 and/or the insulating interlayer 110. For example, the capping layer 130 may be formed by depositing a silicon-containing mask material at a temperature of about 400° C. or below. The capping layer 130 may include, e.g., silicon oxynitride (SiON), silicon nitride (SiN), and/or silicon oxide. The silicon oxide may include, e.g., TEOS, PE-TEOS, atomic layer deposition (ALD) oxide, silicon, silicon germanium, polysilicon, silicon-based bottom anti-reflective coating (Si—BARC), etc.

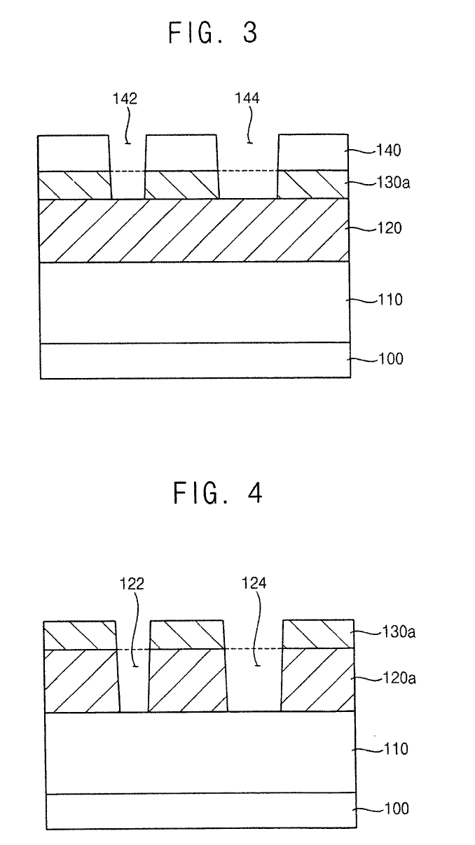

Referring to FIG. 3, a photoresist pattern 140 may be formed on the capping layer 130. Then, a capping layer pattern 130a may be formed by performing an etching process using the photoresist pattern 140 as an etching mask.

The photoresist pattern 140 may be formed of a photoresist material, e.g., ArF photoresist. In an implementation, the photoresist pattern 140 may define at least two types of holes, which may have different dimensions and/or different shapes. For example, the photoresist pattern 140 may include a first hole 142 having a first dimension (e.g., width) and a first shape and a second hole 144 having a second dimension (e.g., width) and a second shape. The photoresist pattern 140 may include a plurality of first holes 142 and a plurality of second holes 144. In an implementation, the first hole 142 may be a circular or round hole and the second hole 144 may be a bar-shaped hole having a short dimension (e.g., width) and a long dimension (e.g., length). The bar-shaped hole may have an aspect ratio of at least about 2. The first hole 142 and the second hole 144 may have the same or different critical dimensions. In an implementation, the second hole 144 may have at least one dimension, e.g., width, that is at least twice as large than that of the first hole 142.

In an implementation, an anti-reflective coating layer (not illustrated) may be formed on the capping layer 130 prior to forming the photoresist pattern 140. In this case, the photoresist pattern 140 may be formed on the anti-reflective coating layer. The anti-reflective coating layer and the capping layer 130 may be patterned using the photoresist pattern 140 as a mask.

A portion of the capping layer 130 exposed through the photoresist pattern 140 may be etched to form a capping layer pattern 130a on the carbon-containing layer 120. The capping layer 130 may be etched by, e.g., a dry etching process and/or a wet etching process. The capping layer pattern 130a may have holes corresponding to the first hole 142 and the second hole 144 of the photoresist pattern 140. The photoresist pattern 140 may be partially or totally removed from the substrate 100 while patterning the capping layer 130. In an implementation, the photoresist pattern 140 may be removed by, e.g., a stripping process or an ashing process.

Referring to FIG. 4, the carbon-containing layer 120 may be etched using the capping layer pattern 130a as an etching mask to form a carbon-containing layer pattern 120a on the insulating interlayer 110. For example, the carbon-containing layer 120 may be etched by a plasma etching process using an etching gas including oxygen and an inert gas. The inert gas may include xenon gas (Xe). In an implementation, the inert gas may be xenon gas (Xe) or a gas mixture of xenon gas and at least one other inert gas (e.g., Ar, Ne, Kr, etc.). The carbon-containing layer pattern 120a may have holes corresponding to the holes in the capping layer pattern 130a. In an implementation, the carbon-containing layer 120 may be anisotropically etched to form holes having slanted sidewalls.

The carbon-containing layer pattern 120a may have a third hole 122 corresponding to the first hole 142 of the photoresist pattern 140a and a fourth hole 124 corresponding to the second hole 144 of the photoresist pattern 140a. The third hole 122 and the fourth hole 124 may have a slightly slanted sidewall. In an implementation, the fourth hole 124 may have at least one dimension, e.g., width, that is at least twice as large as that of the third hole 122.

The carbon-containing layer 120 may be etched using an etching gas that includes oxygen gas and an inert gas (e.g., xenon gas, or a gas mixture of xenon gas and argon gas). The ratio {Xe/(Ar+Xe)} of the amount of xenon gas to the total amount of the gas mixture of xenon gas and argon gas may be about 0.2 to about 1.0. Preferably, the ratio is about 0.25 to about 1.0. When the amount of oxygen gas in the etching gas is about 50 to about 75% by volume, the amount of xenon gas or the gas mixture of xenon gas and argon gas may be about 25 to about 50% by volume. When the amount of oxygen gas in the etching gas is about 60 to about 75% by volume, the amount of xenon gas or the gas mixture of xenon gas and argon gas may be about 25 to about 40% by volume. Maintaining the amount of the inert gas including xenon at about 25 to about 50% by volume may help ensure that an etching rate or an etching ability of the carbon-containing layer is improved and/or anisotropic etching ability of the plasma etching process is enhanced, due to an increase in an ion flux amount of the etching gas. When the ratio of the amount of xenon gas to the total amount of the gas mixture of xenon gas and argon gas is about 0.5 to about 1.0, the etching rate of the carbon-containing layer may be about 5,450 to about 5,600 Å/min.

In an implementation, a passivation gas may be used in the etching process. The passivation gas may be provided together with the etching gas to improve the anisotropic etching ability of the carbon-containing layer. For example, CO, HBr, Cl₂, COS, N₂, SO₂, NO, and/or NO₂ may be used as the passivation gas.

Xenon gas included in the etching gas may have an ionization energy lower than that of argon gas. Therefore, xenon gas may be readily ionized to raise the ion flux of plasma in the etching gas and thereby improve anisotropic etching ability. Accordingly, the carbon-containing layer may be plasma-etched using an etching gas including xenon gas so that an etching rate or an etching ability of the carbon-containing layer may be improved. In addition, anisotropic etching ability of the plasma etching process may be enhanced due to an increase in an ion flux amount of the etching gas. In the etching process for forming holes in an insulation layer using a carbon-containing mask layer, the size of the holes formed in the insulation layer may decrease as the relative amount of xenon gas increases in the etching gas used to etch the carbon containing layer. Further, when contact holes having at least two different sizes and/or shapes are formed in the insulation layer using the carbon-containing mask layer, the size (especially, the bottom size) of the contact holes may vary in a similar proportion to each other regardless of the sizes and/or shapes of the contact holes. Therefore, the size of the holes in the insulation layer may be readily adjusted by varying the amount of xenon gas in the etching gas used to etch the carbon-containing layer.

The carbon-containing layer pattern 120a may have the third hole 122 and the fourth hole 124. Even though the third hole 122 and the fourth hole 124 may have different sizes and/or shapes, the sizes of the third hole 122 and the fourth hole 124 formed in the carbon-containing layer pattern 120a may be easily adjusted by changing the amount of xenon gas in the etching gas, since the size of the third hole 122 and the fourth hole 124 may vary proportionally regardless of the sizes and/or shapes of the third hole 122 and the fourth hole 124. The third hole 122 and the fourth hole 124 in the carbon-containing layer pattern 120a may be smaller than the first hole 142 and the second hole 144 of the photoresist pattern 140. This may be due to, e.g., skew of the third hole 122 and the fourth hole 124. The skew may be a difference in size between a hole in the photoresist pattern 140 and a hole formed in a layer under the photoresist pattern 140.

In an implementation, when the ratio {Xe/(Ar+Xe)} of the amount of xenon gas to the total amount of the gas mixture of argon gas and xenon gas increases, e.g., from about 0.25 to about 1.0, the sizes of the third hole 122 and the fourth hole 124 may decrease in a similar or constant proportion to one another. A first deviation may be a difference in size of the first hole 142 and the third hole 122, and a second deviation may be a difference in size of the second hole 144 and the fourth hole 124. When the ratio {Xe/(Ar+Xe)} of the amount of xenon gas to the total amount of the gas mixture of argon gas and xenon gas increases, e.g., from about 0.25 to about 1.0, the first deviation and the second deviation may not vary significantly. Accordingly, differences between the first deviation and the second deviation may be relatively small.

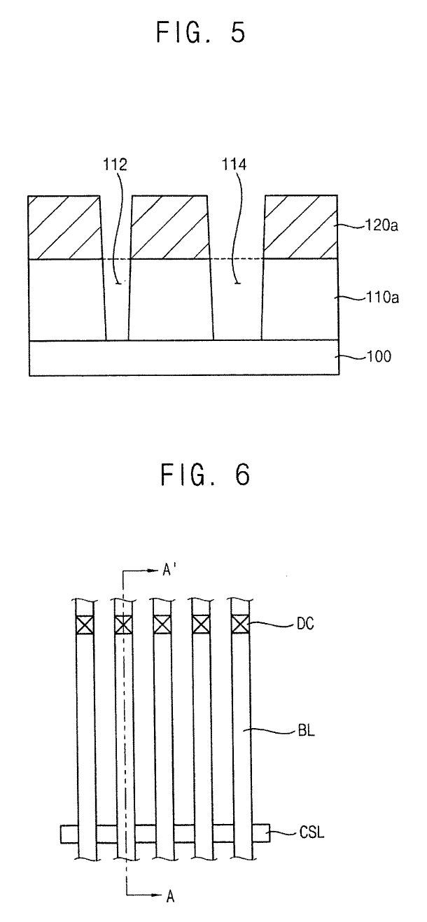

Referring to FIG. 5, the insulating interlayer 110 may be dry-etched using the carbon-containing layer pattern 120a as an etching mask. After forming the carbon-containing layer pattern 120a, the capping layer pattern 130a may be removed. If the capping layer pattern 130a remains on the carbon-containing layer pattern 120a, the insulating interlayer 110 may be etched using both the carbon-containing layer pattern 120a and the capping layer pattern 130a as etching masks. By etching the insulating interlayer 110, an insulating interlayer pattern 110a having a first contact hole 112 and a second contact hole 114 may be formed on the substrate 100.

The first contact hole 112 and the second contact hole 114 of the insulating interlayer 110 may correspond to the third hole 122 and the fourth hole 124 of the carbon-containing layer pattern 130a. The first contact hole 112 and the second contact hole 114 may have different sizes and/or shapes from one another. In an implementation, the first contact hole 112 may have, e.g., a circular or round shape, and the second contact hole 114 may have, e.g., a bar shape with an aspect ratio of, e.g., about 2 to about 30. In another implementation, the first contact hole 112 may be smaller than the first hole 142 of the photoresist pattern 140 and the second contact hole 114 may be smaller than the second hole 144 of the photoresist pattern 140. A first skew may be defined as a difference in size between the first hole 142 of the photoresist pattern 140 and the first contact hole 112 and a second skew may be defined as a difference in size between the second hole 144 of the photoresist pattern 140 and the second contact hole 114. When the ratio {Xe/(Ar+Xe)} of the amount of xenon gas to the total amount of the gas mixture of argon gas and xenon gas increases, e.g., from about 0.25 to about 1.0, or from about 0.5 to about 1.0, the first skew and the second skew may not vary significantly. In other words, variations between the first skew and the second skew may be relatively small. In an implementation, the first skew between the first hole 142 and the first contact hole 112 and the second skew between the second hole 144 and the second contact hole 114 may differ by about 15 nm or less.

In an implementation, the ratio {Xe/(Ar+Xe)} of the amount of xenon gas to the total amount of the gas mixture of argon gas and xenon gas may be, e.g., from about 0.5 to about 1.0. In this case, the size of the third hole 122 and the fourth hole 124 in the carbon-containing layer pattern 120 may gradually decrease. Accordingly, the dimensions, e.g., widths or diameters, of the first contact hole 112 and the second contact hole 114 formed in the insulating interlayer pattern 110a may also decrease in a similar or constant proportion.

The method of forming contact holes in an insulation layer as described above may be applied to a method of manufacturing various memory devices or integrated circuit devices. For example, the method may be employed in manufacturing a flash memory device, a DRAM device or a phase-change random access memory (PRAM) device, which may have a critical dimension of about 50 nm or less. As an example, a method of manufacturing a flash memory device that includes an insulating interlayer having contact holes will be described herein. However, other memory device (e.g., a DRAM device) or other integrated circuit devices, which may include an insulating interlayer having contact holes, may be manufactured in a similar manner.

Method of Manufacturing a Flash Memory Device

FIG. 6 illustrates a layout view of an NAND-type flash memory device manufactured by the method of forming a contact hole according to an embodiment. Recently, highly integrated memory devices having a critical dimension of about 50 nm or less have been in demand. Referring to FIG. 6, a portion of a cell block that may be employed in an NAND-type flash memory device is illustrated and, particularly, an array of direct contacts (DC) being connected to bit lines (BL) and a common source line (CSL) are illustrated. The direct contacts may be arranged at intervals of about several tens of nanometers (e.g., about 40 nm or less). The flash memory device including the direct contacts may be manufactured by the method of forming contact holes in an insulating interlayer using the carbon-containing layer pattern as an etching mask.

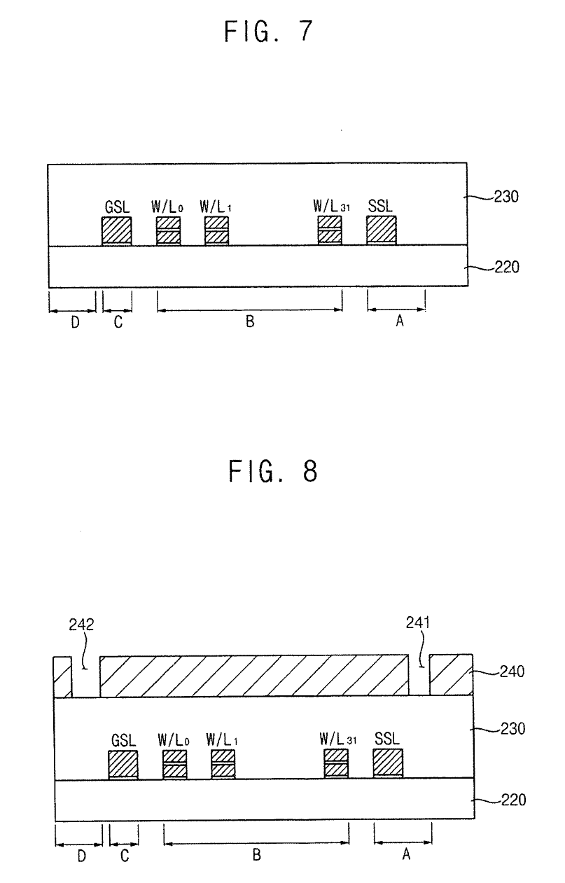

FIGS. 7 through 10 illustrate cross-sectional views of stages in a method of manufacturing an NAND-type flash memory device according to an embodiment. Referring to FIG. 7, a substrate 220 may be prepared. In an implementation, the substrate 220 may be a single crystalline substrate. The substrate 220 may include, e.g., a silicon wafer, a silicon-on insulator (SOI) substrate, a germanium substrate, a silicon germanium substrate, etc. The substrate 220 may include, e.g., a single crystalline thin film formed from an amorphous film by phase transition. For example, the substrate 220 may be a single crystalline silicon substrate. The substrate 220 may include a string selection transistor region (A), a memory cell region (B), a ground selection transistor region (C), and a common source line region (D).

A string selection line (SSL), a ground selection line (GSL), and memory cells (W/L_{0˜31}) may be formed on the substrate 220. The string selection line (SSL) and the ground selection line (GSL) may have a stacked structure including a gate oxide layer and a gate electrode. The memory cells may have a stacked structure including a tunnel insulation layer, a floating gate, a dielectric layer, and a control gate.

An insulating interlayer 230 may be formed on the substrate 220 to cover the string selection line (SSL), the ground selection line (GSL), and the memory cells (W/L_{0˜31}) The insulating interlayer 230 may be formed from an insulating material. For example, the insulating interlayer 230 may be formed using silicon oxide. The silicon oxide may include, e.g., BPSG, PSG, USG, SOG, FOX, PE-TEOS, HDP-CVD oxide, etc.

Referring to FIG. 8, a carbon-containing layer pattern 240 may be formed on the insulating interlayer 230. The carbon-containing layer pattern 240 may be formed by partially plasma-etching a carbon-containing layer using an etching gas including oxygen gas and xenon gas. The carbon-containing layer pattern may be formed by the method described with reference to FIGS. 3 and 4. In an implementation, the carbon-containing layer pattern 240 may include a third hole 241 defining a region for forming a direct contact (DC) and a fourth hole 242 defining a region for forming a common source line (CSL). In an implementation, the third hole 241 may be a fine circular hole and the fourth hole 242 may be a bar-shaped hole. The third hole 241 may have a size or a width smaller than a size or a width of the fourth hole 242. The third hole 241 may have a width smaller than a width of the first hole 142 (see FIG. 3) of the photoresist pattern 140 and the fourth hole 242 may have a width smaller than a width of the second hole 144 (see FIG. 3) of the photoresist pattern 140.

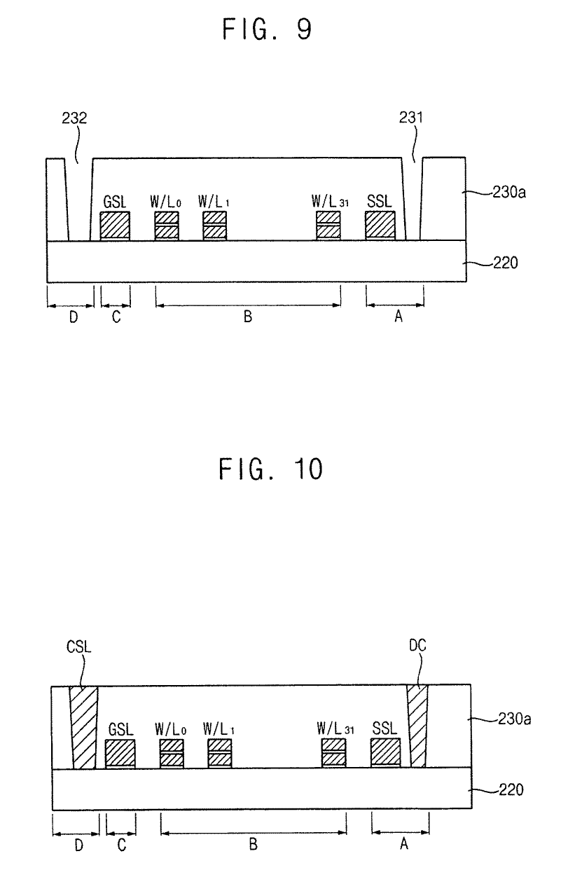

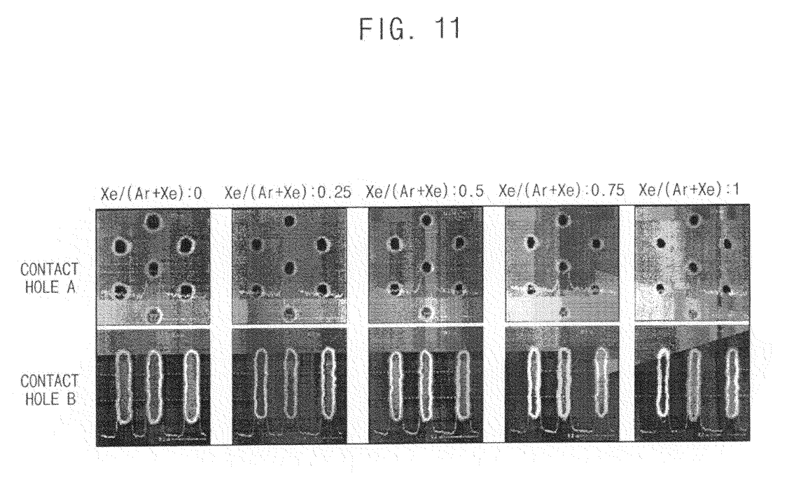

Referring to FIG. 9, the insulating interlayer 230 may be partially etched using the carbon-containing layer pattern 240 as an etching mask. The insulating interlayer 230 may be etched by, e.g., a dry etching process and/or a wet etching process. By patterning the insulating interlayer 230, an insulating interlayer pattern 230a including a first contact hole 231 and a second contact hole 232 exposing a portion of the substrate 220 may be formed on the substrate 220. The first contact hole 231 may expose an impurity region of the substrate 220 adjacent to the string selection line SSL (A), and the second contact hole 232 may expose a region (D) for forming the common source line CSL. The first contact hole 231 may have a circular shape and the second contact hole 232 may have one of a line shape or a bar shape. The first contact hole 231 and/or the second contact hole 232 may have a critical dimension (i.e., the smallest size) of about 50 nm or less (e.g., about 40 nm). The first contact hole 231 may include a plurality of holes arranged at an interval of, e.g., about 40 to about 50 nm, parallel to a lengthwise direction of the common source line (CSL).

Referring to FIG. 10, the carbon-containing layer pattern 240 may be removed from the substrate 220. A conductive layer (not shown) may be formed on the insulating interlayer pattern 230a to fill the first contact hole 231 and the second contact hole 232. An upper portion of the conductive layer may be removed by, e.g., a polishing process, until the insulating interlayer pattern 230a is exposed. The partial removal of the conductive layer may be performed by, e.g., a chemical mechanical polishing process. As a result, a direct contact (DC) may be formed in the first contact hole 231 and a common source line (CSL) may be formed in the second contact hole 232. A bit line (not shown) and/or a bit line contact (not shown) may be formed on the insulating interlayer pattern 230a to be electrically connected to the direct contact (DC). The method of forming contact holes in the insulating interlayer may be applied to, e.g., contact holes for a bit line contact and/or a metal contact included in various memory devices or integrated circuit devices.

Evaluation of a Width Variation of a Contact Hole According to an Amount Change of Xenon Gas Used in Etching a Carbon-Containing Layer

Samples were prepared for evaluating width variation of contact holes in an insulating interlayer according to an amount of xenon gas used during etching of a carbon-containing layer. A silicon oxide layer was formed on a silicon wafer as an insulating interlayer. An amorphous carbon layer was formed on the silicon oxide layer to a thickness of about 8,000 Å. A silicon oxynitride capping layer was formed on the amorphous carbon layer to a thickness of about 260 Å. A photoresist pattern was formed on the silicon oxynitride capping layer to define a circular first hole and a bar-shaped second hole. The silicon oxynitride capping layer, the amorphous carbon layer and the silicon oxide layer were patterned using a CCP-type dual plasma etching apparatus. In an etching process for patterning the silicon oxynitride capping layer, an etching gas including CF₄, CHF₃ and O₂ was used. The silicon oxynitride capping layer pattern was formed by patterning a silicon oxynitride layer using the photoresist pattern as a mask. The silicon oxynitride capping layer pattern was formed to have a circular first hole and a bar-shaped second hole. After forming the silicon oxynitride capping layer pattern, an etching process for patterning the amorphous carbon layer was performed using an etching gas including oxygen gas as a base gas and an inert gas (xenon gas or a gas mixture of xenon gas and argon gas). The ratio {Xe/(Ar+Xe)} of the amount of xenon gas to the total amount of the inert gas mixture was adjusted incrementally from about 0 to about 1 and the samples were plasma-etched. In this plasma etching process, a process temperature (e.g., a temperature of the silicon wafer) was about 30° C., a pressure was about 15 mTorr, a flow rate of oxygen (O₂) gas was about 700 sccm, and a flow rate of the inert gas was about 400 sccm. An etching process was performed on the silicon oxide layer using the amorphous carbon layer pattern as an etching mask. In the etching process for patterning the silicon oxide layer, an etching gas including C₄F₈, Ar and O₂ was used. By performing plasma etching processes, a first contact hole (A) and a second contact hole (B) were formed in the silicon oxide layer. The first contact hole (A) had a circular shape and the second contact hole (B) had a bar or line shape having an aspect ration of about 10.

FIG. 11 illustrates SEM images showing the first and the second contact holes obtained by incrementally varying the ratio of xenon gas and argon gas in the etching gas for etching the carbon-containing layer. Referring to FIG. 11, sizes of a first contact hole (A) and a second contact hole (B) formed in a silicon oxide layer gradually decreased, as the ratio {Xe/(Ar+Xe)} of the amount of xenon gas to the total amount of the inert gas portion of the gas used in etching the amorphous carbon layer increased incrementally from about 0 (Xe gas: 0 sccm) to about 1 (Xe gas: 400 sccm). The size (e.g., width) of the first contact hole (A) decreased from about 60 nm to about 38 nm as the ratio {Xe/(A+Xe)} of the amount of xenon gas to the total amount of the inert gas portion of the etching gas used in etching the amorphous carbon layer increased from about 0 to about 1. The size (e.g., width of the short axis) of the second contact hole (B) decreased from about 60 nm to about 35 nm as the ratio {Xe/(A+Xe)} of the amount of xenon gas to the total amount of the inert gas portion of the etching gas used in etching the amorphous carbon layer increased from about 0 to about 1.

FIG. 12 illustrates a graph showing skew variations of the first and the second contact holes obtained by incrementally varying the ratio of xenon gas and argon gas in an etching gas for etching a carbon-containing layer. In FIG. 12, the units of skew are nanometers, and the skew denotes a width difference between a hole formed in a photoresist pattern and a contact hole in the insulating silicon oxide layer formed using the amorphous carbon mask. The skew of the first contact hole (A) is a first skew, and the skew of the second contact hole (B) is a second skew. Referring to FIG. 12, when the ratio {Xe/(Ar+Xe)} of the amount of xenon gas to the total amount of the inert gas portion of the etching gas is about 0, the first skew of the first contact hole (A) is positive and the second skew of the second contact hole (B) is negative. This means that the first contact hole has a width smaller than a (predetermined) hole width of the photoresist pattern, and the second contact hole has a width larger than a hole width of the photoresist pattern. However, as the ratio of the amount of xenon gas increased from about 0.25 to about 1, both the first skew and the second skew varied only slightly in a relatively narrow range. In addition, a difference between the first skew and the second skew was constantly maintained without an abrupt variation. The first skew between the first hole of the photoresist pattern and the first contact hole of the insulation layer and the second skew between the second hole of the photoresist pattern and the second contact hole of the insulation layer differed by about 15 nm or less.

Evaluation of an Etching Rate of an Amorphous Carbon Layer According to an Amount of Xenon Gas

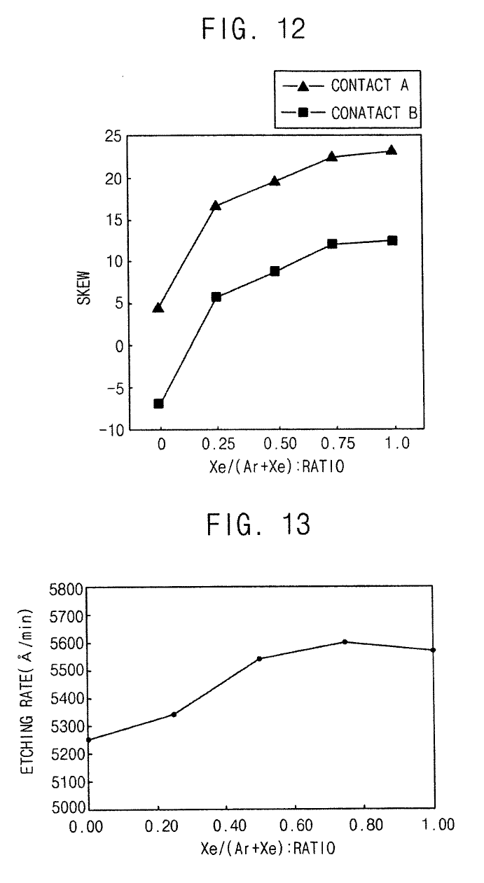

FIG. 13 illustrates a graph showing variation of an etching rate of an amorphous carbon layer according to the amount of xenon gas in the mixed xenon and argon inert portion of the etching gas. Referring to FIG. 13, the etch rate of the amorphous carbon layer increased as the ratio {Xe/(Ar+Xe)} of the amount of the xenon gas to the total amount of the inert gas portion of the etching gas incrementally increased. When the ratio of xenon gas in the gas mixture of argon gas and xenon gas was at least about 0.5, the etch rate of the amorphous carbon layer greatly increased up to at least about 200 Å/min.

Memory Device

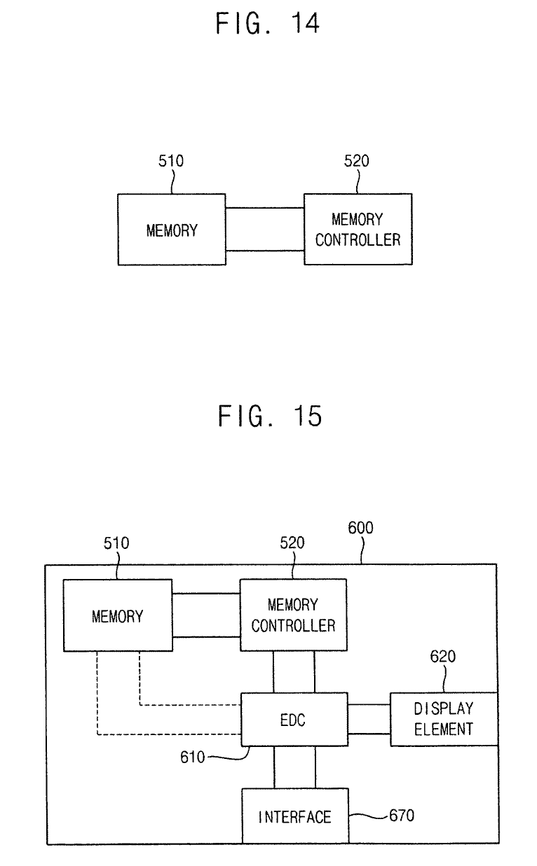

FIG. 14 illustrates a block diagram of a memory device according to an embodiment. Referring to FIG. 14, a memory controller 520 may be connected to a memory 510. The memory 510 may be, e.g., a flash memory or a DRAM device, which includes pads formed in the contact holes obtained by the method of an embodiment described above. The flash memory device may be, e.g., an NAND flash memory or an NOR flash memory. The memory controller 520 may provide the memory 510 with input signals to control operations of the memory 510. In a memory card of an embodiment, the memory controller 520 may transfer commands of a host to the memory 510 to control input/output data and/or may control various data of a memory based on an applied control signal. Such a structure or a relation may be employed in various digital devices using a memory as well as the simple memory card.

Portable Device

FIG. 15 illustrates a block diagram of a portable device according to an embodiment. Referring to FIG. 15, a portable device 600 may be provided according to an embodiment. The portable device 600 may include, e.g., an MP3 player, a video player, a portable multi-media player (PMP), etc. The portable device 600 may include the memory 510, the memory controller 520, an encoder/decoder (EDC) 610, a display element 620, and an interface 630. The memory 510 may be a flash memory or a DRAM device, which includes pads formed in the contact holes obtained by the method of an embodiment.

Data may be input to or output from the memory 510 by way of the memory controller 520. As illustrated in dotted lines of FIG. 15, data may be directly input from the EDC 610 to the memory 510, or directly output from the memory 510 to the EDC 610.

The EDC 610 may encode data to be stored in the memory 510. For example, the EDC 610 may encode for storage of audio data and/or video data in the memory 510 of an MP3 player or a PMP player. Further, the EDC 610 may encode MPEG data for storing video data in the memory 510. The EDC 610 may include multiple encoders for encoding different types of data depending on their formats. For example, the EDC 610 may include an MP3 encoder for encoding audio data and an MPEG encoder for encoding video data.

The EDC 610 may decode data being output from the memory 510. For example, the EDC 610 may decode MP3 audio data from the memory 510. In an implementation, the EDC 610 may decode MPEG video data from the memory 510. The EDC 610 may include multiple decoders to encode/decode different types of data depending on their formats. For example, the EDC 610 may include an MP3 decoder for audio data and an MPEG decoder for video data.

The EDC 610 may include only a decoder. For example, encoded data may be input to the EDC 610, and then the EDC 610 may decode the input data to transfer into the memory controller 520 or the memory 510.

The EDC 610 may receive data to be encoded or data being encoded by way of the interface 630. The interface 630 may comply with established standards, e.g. FireWire, USB, etc. The interface 630 may include, e.g., a FireWire interface, an USB interface, etc. Data may be output from the memory 510 by way of the interface 630.

The display element 620 may display data output from the memory 510 and decoded by the EDC 610. Examples of the display element 620 may include a speaker outputting audio data, a display screen outputting video data, etc.

Computer System

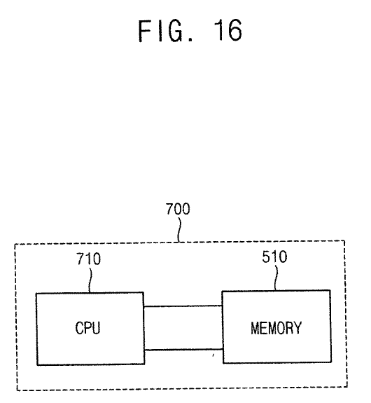

FIG. 16 illustrates a block diagram of a computer system according to an embodiment. Referring to FIG. 16, a computing system 700 may be provided according to an embodiment. The computing system 700 may include the memory 510 and a central processing unit (CPU) 710 connected to the memory 510. The memory 510 may be a flash memory or a DRAM device, which includes pads formed in the contact holes obtained by the method of an embodiment. An example of the computing system 700 may be a laptop computer including a flash memory as a main memory. Examples of the computing system 700 may include digital devices in which the memory 510 for storing data and controlling functions may be built. The memory 510 may be directly connected to the CPU 710, or indirectly connected to the CPU 710 by buses. Although not illustrated in FIG. 16, other elements or devices may be incorporated in the computing system 700.

According to an embodiment, the size or critical dimension of a hole formed in the carbon-containing layer pattern may be reduced by using an etching gas that includes oxygen gas and xenon gas, which has a relatively low ionization energy. A contact hole formed in an insulation layer using the carbon-containing layer pattern as an etching mask may also have a decreased size or critical dimension. By adding xenon gas to the etching gas, or raising the ratio of xenon gas in the etching gas, sizes of contact holes having different shapes formed in the insulation layer may be reduced while skew variations among the contact holes may also be suppressed. Further, a relatively large amount of xenon gas in the etching gas may also increase an etching rate of the carbon-containing layer to improve etching efficiency and to reduce loss of a mask layer or a capping layer formed on the carbon-containing layer.

Exemplary embodiments have been disclosed herein, and although specific terms are employed, they are used and are to be interpreted in a generic and descriptive sense only and not for purpose of limitation. Accordingly, it will be understood by those of ordinary skill in the art that various changes in form and details may be made without departing from the spirit and scope of the present invention as set forth in the following claims.

What is claimed is:

1. A method of etching a carbon-containing layer, comprising:
forming a capping layer pattern on a carbon-containing layer to expose a portion of the carbon-containing layer; and
plasma etching the exposed portion of the carbon-containing layer using an etching gas, wherein the etching gas includes oxygen gas and an inert gas, the inert gas being xenon gas or a gas mixture of xenon gas and argon gas.

2. The method as claimed in claim 1, wherein an amount of the inert gas included in the etching gas is about 25% to about 50% by volume, based on the total volume of the etching gas.

3. The method as claimed in claim 1, wherein:
the inert gas is the gas mixture of xenon gas and argon gas, and
a ratio {Xe/(Ar+Xe)} of an amount of xenon gas to a total amount of xenon gas and argon gas is about 0.2 to about 1.0.

4. The method as claimed in claim 3, wherein the ratio {Xe/(Ar+Xe)} of the amount of xenon gas to the total amount of xenon gas and argon gas is about 0.5 to about 1.0.

5. The method as claimed in claim 1, wherein an amount of xenon gas in the etching gas is about 5% to about 50% by volume, based on the total volume of the etching gas.

6. The method as claimed in claim 1, wherein plasma etching the carbon-containing layer further includes providing a passivation gas including at least one of CO, HBr, Cl₂, COS, N₂, SO₂, NO, and NO₂.

7. The method as claimed in claim 1, wherein the carbon-containing layer includes at least one of an amorphous carbon layer (ACL), a carbon based spin-on hardmask (C—SOH), and a nanocarbon polymer.

8. The method as claimed in claim 1, including forming a capping layer on the carbon-containing layer such that the capping layer includes at least one of a silicon oxide layer, a silicon oxynitride layer, a silicon layer, a silicon germanium layer, and a polysilicon layer,
wherein the forming the capping layer pattern includes:
forming a photoresist pattern on the capping layer, and
patterning the capping layer by performing an etching process using the photoresist pattern as an etching mask.

9. The method as claimed in claim 8, further comprising forming an organic anti-reflective coating layer on the capping layer.

10. A method of forming an insulation layer having a contact hole, comprising:
forming an insulation layer on a substrate;
sequentially forming a carbon-containing layer and a capping layer on the insulation layer;
forming a photoresist pattern on the capping layer, the photoresist pattern including a first hole and a second hole having a size or a shape different from a size or a shape of the first hole;
partially etching the capping layer using the photoresist pattern on the capping layer as a mask to form a capping layer pattern which partially exposes the carbon-containing layer;
etching a portion of the carbon-containing layer exposed by the capping layer pattern using an etching gas that includes oxygen gas and an inert gas including xenon gas to form a carbon-containing layer pattern on the layer; and
etching a portion of the insulation layer exposed by the carbon-containing layer pattern to form a first contact hole and a second contact hole in the insulation layer.

11. The method as claimed in claim 10, wherein at least one of the first contact hole and the second contact hole has a width of about 50 nm or less.

12. The method as claimed in claim 10, wherein:
the first contact hole has a round shape, and
the second contact hole has a bar shape having an aspect ratio of at least about 2.

13. The method as claimed in claim 10, wherein:
the carbon-containing layer includes at least one of an amorphous carbon layer (ACL), a carbon based spin-on hardmask (C—SOH), and a nanocarbon polymer, and
the capping layer includes at least one of a silicon oxide layer, a silicon oxynitride layer, a silicon layer, a silicon germanium layer, and a polysilicon layer.

14. The method as claimed in claim 10, further comprising forming an organic anti-reflective coating layer on the capping layer.

15. The method as claimed in claim 10, wherein the inert gas further includes argon gas.

16. The method as claimed in claim 15, wherein a ratio {Xe/(Ar+Xe)} of an amount of xenon gas to a total amount of xenon gas and argon gas is about 0.2 to about 1.0.

17. The method as claimed in claim 10, wherein the etching a portion of the carbon-containing layer further includes providing a passivation gas including at least of CO, HBr, Cl₂, COS, N₂, SO₂, NO, and NO₂.

18. The method as claimed in claim 12, wherein:
a first skew exists between the first hole in the photoresist pattern and the first contact hole of the insulation layer,
a second skew exists between the second hole in the photoresist pattern and the second contact hole of the insulation layer, and
a dimensional difference between the first skew and the second skew is about 15 nm or less.

19. A method of manufacturing a semiconductor device, comprising:
forming an insulating interlayer on a substrate;
sequentially forming a carbon-containing layer and a capping layer on the insulating interlayer;
forming a photoresist pattern on the capping layer, the photoresist pattern including a plurality of first holes having a round shape and a plurality of second holes having one of a bar shape or a line shape;
partially etching the capping layer using the photoresist pattern on the capping layer as a mask to form a capping layer pattern;
etching a portion of the carbon-containing layer exposed by the capping layer pattern using an etching gas that includes oxygen gas and an inert gas including xenon gas to form a carbon-containing layer pattern on the layer;
etching a portion of the insulation layer exposed by the carbon-containing layer pattern to form a plurality of first contact holes in the insulation layer corresponding to the first holes and a plurality of second contact holes in the insulation layer corresponding to the second holes; and
filling the plurality of first contact holes and the plurality of second contact holes with a conductive material to form a plurality of first contacts and a plurality of second contacts on the substrate,
wherein at least one of the first contacts and the second contacts has a width of about 50 nm or less.
